(19) United States
(12) Patent Application Publication
(10) Pub. No.: US 2008/0086781 A1
(43) Pub. Date: Apr. 10, 2008

(54) METHOD AND SYSTEM FOR GLITCH PROTECTION IN A SECURE SYSTEM

(76) Inventor: Stephane Rodgers, San Diego, CA (US)

Correspondence Address: MCANDREWS HELD & MALLOY, LTD, 500 WEST MADISON STREET, SUITE 3400, CHICAGO, IL, 60661, US

(21) Appl. No.: 11/741,990

(22) Filed: Apr. 30, 2007

Related U.S. Application Data
(60) Provisional application No. 60/828,571, filed on Oct. 6, 2006.

(51) Int. Cl. G08B 29/12; G01R 31/3193

(52) U.S. Cl. 726/34; 714/733

(57) ABSTRACT

Aspects of a method and system for glitch protection in a secure system are provided. In this regard, the output of an on-chip security operation may be combinatorially compared with an expected output of the security operation. Based on the results of the comparison, one or more signals which may control access to one or more on-chip secure functions may be generated. The security operation may, for example, comprise generating a message digest utilizing a SHA and/or modifying a stored value based on an amount of code being executed. The expected output may comprise a single value or range of values. In this regard, a system may, for example, be protected from glitch attacks causing lines-of code to be skipped and or causing enable signals to be forced to an illegitimate value.

### CROSS-REFERENCE TO RELATED APPLICATIONS/INCORPORATION BY REFERENCE

This patent application makes reference to, claims priority to and claims benefit from U.S. Provisional Patent Application Ser. No. 60/828,571 filed on Oct. 6, 2006.

The above stated application is hereby incorporated by reference in its entirety.

### FIELD OF THE INVENTION

Certain embodiments of the invention relate to secure communication of information. More specifically, certain embodiments of the invention relate to a method and system for glitch protection in a secure system.

### BACKGROUND OF THE INVENTION

In a secure system, many security checks may be implemented to prevent unauthorized access to and/or manipulation of data stored in a system. These security checks may include cryptographic operations and may be quite secure, with multiple stages of protection. However, in any hardware implementation, the results of these checks may nevertheless funnel down into a narrow logic cone whose output is a single bit or a few bits, which may determine whether the system can be ultimately used. This logic cone is critical to security, because a successful attack against it may bypass all the security in the system.

A glitch attack may refer to a transient disturbance introduced onto one or more signals or voltage lines in a system. In the past, glitch attacks have been used to force hardware into an illegitimate state. In this regard, if a glitch attack were to force the single or few bits of the critical logic cone into an illegitimate state, then security features of the system may be bypassed. In addition, glitch attacks have been used in the past to cause processors to jump around key instructions; instructions which implement some security function. This type of attack is a concern, for example, in a reprogrammable system that uses boot ROM, because the boot ROM may implement critical security functions, which may determine whether access to the system should be granted. For these reasons, glitch attacks must be considered and defended against in order to be able to claim a secure system.

Further limitations and disadvantages of conventional and traditional approaches will become apparent to one of skill in the art, through comparison of such systems with some aspects of the present invention as set forth in the remainder of the present application with reference to the drawings.

### BRIEF SUMMARY OF THE INVENTION

A system and/or method is provided for glitch protection in a secure system, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary secure system, in accordance with an embodiment of the invention.

FIG. 2A is a block diagram of an exemplary system illustrating the need for glitch protection, in connection with an embodiment of the invention.

FIG. 2B is a timing diagram illustrating an exemplary glitch attack on the system 200, in connection with an embodiment of the invention.

FIG. 2C is a timing diagram illustrating an exemplary glitch attack on the system 200, in connection with an embodiment of the invention.

FIG. 3 is a block diagram an exemplary glitch protected system, in accordance with an embodiment of the invention.

FIG. 4A is a diagram of a code sequence illustrating the need for glitch protection, in connection with an embodiment of the invention.

FIG. 4B is a diagram of an exemplary glitch protected system, in accordance with an embodiment of the invention.

FIG. 4C is a diagram illustrating the use of a counter to determine whether code has been executed, in accordance with an embodiment of the invention.

### DETAILED DESCRIPTION OF THE INVENTION

Certain embodiments of the invention may be found in a method and system for glitch protection in a secure system. In various embodiments of the invention, one or more outputs of a security operation may be compared to an expected value and based on the results of the comparison, one or more critical signals may be generated. The critical signals may, for example, enable access to one or more secure functions. In this regard, aspects of the invention may prevent glitch attacks from latching critical signals into illegitimate states. In various embodiments of the invention, one or more security functions may be implemented by a processor and thus may comprise one or more instructions of a code sequence. In this regard, aspects of the invention may enable ensuring that all lines of code comprising the code sequence have been executed.

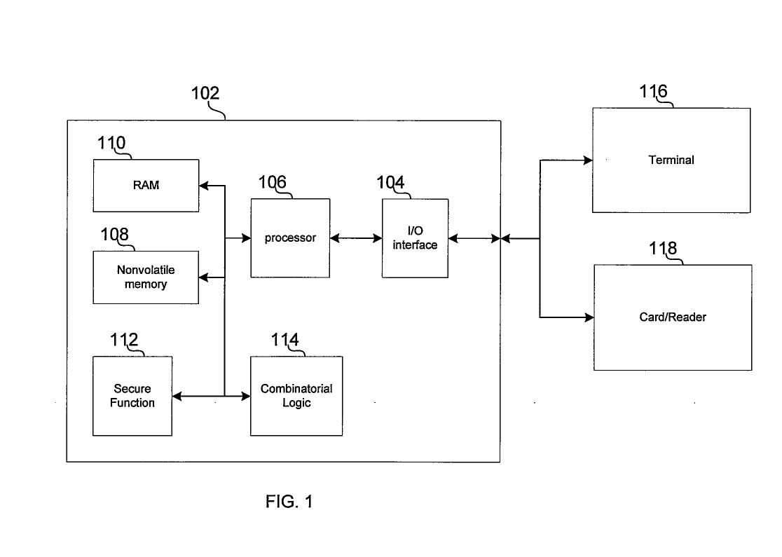

FIG. 1 is a block diagram of an exemplary secure system, in accordance with an embodiment of the invention. Referring to FIG. 1, the exemplary system 102 may comprise an I/O interface 104, a processor 106, a nonvolatile memory 108, and a RAM 110. The exemplary system 102 may be a SoC.

The I/O interface 104 may comprise suitable logic, circuitry, and/or code which may enable communication between the system 102 and an external system. In one embodiment of the invention, the secure system 102 may comprise a smart card and the I/O interface 104 may enable utilizing a terminal 116 or card reader 118 to access and/or modify the information on the card. For example, the I/O interface may enable serial communication with a card reader connected to a PC.

The processor 106 may comprise suitable logic, circuitry, and/or code which may enable processing and/or storing data to/from the I/O interface 104, the nonvolatile memory 108, the RAM 110, the secure function block 112, and the combinatorial logic block 114. The processor 106 may enable verification and/or authentication of the terminal 116 and/or card-reader 118 attempting to communicate via the I/O interface 104. Similarly, the processor 106 may enable verification and/or authentication of data and/or instructions received via the I/O interface 104. In this regard, the processor 106 may perform one or more security checks prior to accessing and/or modifying data in the nonvolatile memory 108, and/or the RAM 110. In one embodiment of the invention, the terminal 116 may connect to the system 102 and may download instructions to the RAM 108. Accordingly, the processor 106 may enable authenticating and/or validating the terminal and/or the downloaded instructions prior to executing the instructions.

The nonvolatile memory 108 may comprise suitable logic, circuitry, and/or code which may enable storing data when the system 108 is not powered. In one embodiment of the invention, the nonvolatile memory 108 may store a set of instructions comprising a boot sequence to load and initialize an operating system. Accordingly, upon connecting to a terminal, the system 102 may power up and the processor 106 may execute the boot sequence.

The RAM 110 may comprise suitable logic, circuitry, and/or code which may enable storing data while the system 102 is powered. In one embodiment of the invention, the RAM 110 may comprise one or more instructions which may be utilized by processor 106. In this regard, the RAM 110 may be loadable by the terminal 116 and, upon the terminal 116 being validated and/or authenticated, the processor 106 may be enabled to execute instructions from the RAM 110.

The secure function block 112 may comprise suitable logic, circuitry, and/or code that may enable implementing one or more security checks. In this regard, the security function block may, for example, enable authenticating and/or validating the terminal 116 and/or the card reader 118.

The combinatorial logic block 114 may comprise suitable logic, circuitry, and/or code that may enable combinatorially comparing two or more signals. In this regard, the combinatorial logic block 114 may, for example, enable comparing the calculated result of a security function with the expected result of that security function.

In operation, the system 102 may be connected to a terminal via the I/O interface 104, and the processor 106 may execute a boot sequence from instructions stored in the non-volatile memory 108. In this regard, the boot sequence may comprise performing one or more operations to establish communication with the terminal 116. For example, the processor 106 may determine the type of terminal to which the system 102 may be connected and the rate and format of information to be exchanged over the I/O interface 104. Upon establishing communication, the boot sequence may comprise performing one or more operations to validate and/or authenticate the terminal 116. The terminal 116 may be permitted to download data and/or instructions to the RAM 110. However, until the terminal 116 has been authenticated and/or validated, the processor 108 may be prevented from executing the instructions stored in the RAM 110. In this manner, one or more critical signals may be utilized to enable execution of instructions from the RAM 110. If a glitch attack is utilized to latch these critical signals to an illegitimate value, then an unauthenticated and/or invalid terminal may be able to execute code from the RAM 110. Additionally, because the boot sequence may implement one or more security features, if a glitch attack causes the processor 106 to skip over a portion of the boot sequence, then an unauthenticated and/or invalid terminal may be able to execute code from the RAM 110. Accordingly, various aspects of the invention may be found in the system 102 to prevent glitch attacks from allowing unauthenticated and/or invalid terminals from executing instruction stored in the RAM 110.

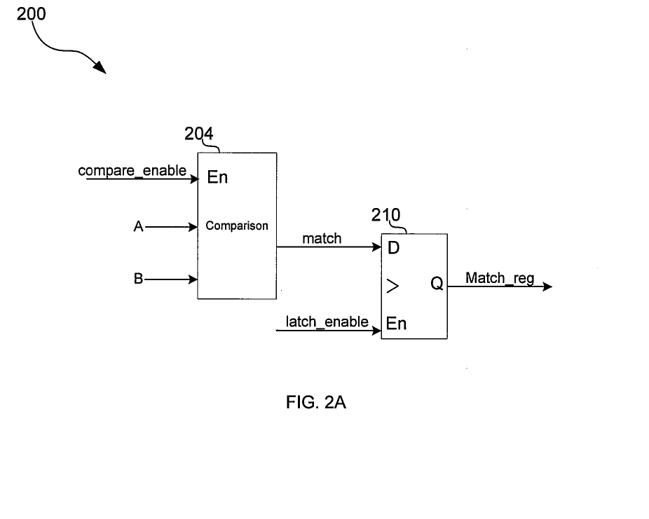

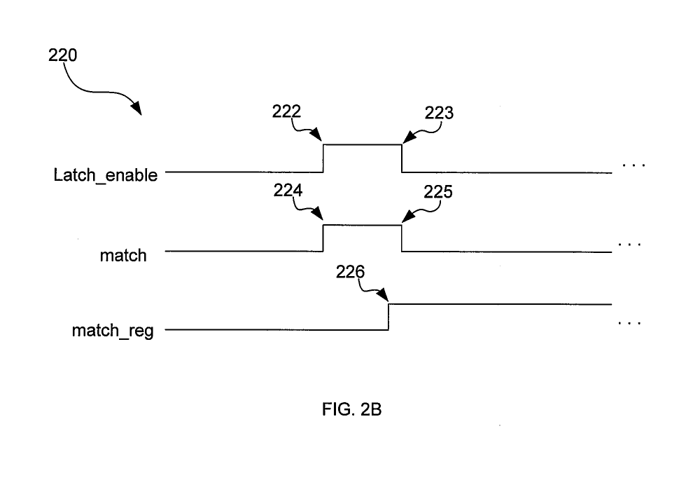

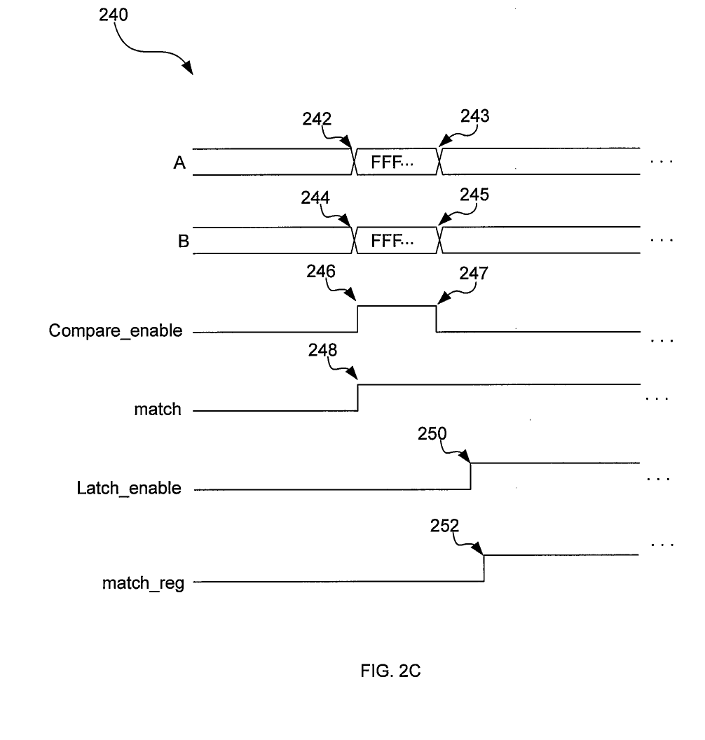

FIG. 2A is a block diagram of an exemplary system 200 illustrating the need for glitch protection, in connection with an embodiment of the invention. Referring to FIG. 2A the exemplary system 200 may comprise a comparison block 204, and a register 210.

The comparison block 204 may comprise suitable logic, circuitry, and/or code which may enable comparing a value ‘A’ to a value ‘B’ and outputting a ‘match’ signal. In this manner, the comparison block may enable setting ‘match’ to logic 1 when ‘A’ is the same as ‘B’, and may enable setting ‘match’ to logic 0 when ‘A’ is not the same as ‘B’. Values ‘A’ and ‘B’ may comprise one or more bits, and may require some settling/processing time before they may become stable. In this regard, the comparison block 204 may contain one or more registers and the value of the registers may be updated when the ‘compare_signal’ is logic 1, and the value of the registers may be retained, independent of ‘A’ and ‘B’, when the signal ‘compare_enable’ may be logic 0.

The register 210 may comprise suitable logic, circuitry, and/or code which may enable storing the value of the ‘match’ as ‘match₁₃ reg’. The register 210 may comprise any combination of latches and/or flip-flops and may have one or more ‘latch_enable’ signals. The register 210 may be utilized, for example, to delay ‘match’ or synchronize it to a clock signal.

In operation, the values ‘A’ and ‘B’ may calculated by, for example, a processor such as the processor 106 of FIG. 1. In this manner, when the processor 106 has completed calculating ‘A’ and ‘B’, the processor 106 may set the signal ‘compare_enable’ to logic 1. Once enabled, the comparison block 204 may set the signal ‘match’ to logic 1 if ‘A’ is the same as ‘B’. The comparison block 204 may set the signal ‘match’ to logic 0 if ‘A’ and ‘B’ are not the same. In this regard, ‘A’ may comprise a calculated result of a security operation and ‘B’ may comprise the expected result of the security operation. If the signal ‘match’ is set to logic 1, this may indicate that some data has passed a security check. Because the signal ‘match’ may not be synchronized or may need to be delayed, the register 210 may store a value of the signal ‘match’ as ‘match’ reg. In this regard, when the signal ‘latch_enable’ is logic 1, the present value of the signal ‘match’ may be stored as ‘match_reg’. When the signal ‘latch_enable’ is logic 0, the values of ‘match_reg’ may be retained and be independent of the present value of the signal ‘match’.

For the secure system of FIG. 2A, a glitch attack may occur in several ways. For example, a glitch attack may occur by inducing a glitch on the ‘match’ and the ‘latch_enable’ signals to force ‘match_reg’ to an illegitimate logic 1; thus bypassing the security features utilized in generating the ‘match’ signal. A glitch attack of this type is illustrated in FIG. 2B. Similarly, a second type of glitch attack may induce glitches on the values of ‘A’, ‘B’, and ‘compare_enable’ such that all bits of ‘A’ and ‘B’ are the same (either all 0's or all 1's) simultaneously, and thus triggering a logic 1 value on the ‘match’ signal. A glitch attack of this type is illustrated in FIG. 2C.

FIG. 2B is a timing diagram illustrating how a glitch attack may bypass security features in a system, in connection with an embodiment of the invention. Referring to FIG. 1B, the timing diagram illustrates the effect of a glitch attack on the ‘latch_enable’, ‘match’, and ‘match_reg’ signals described in FIG. 2A. In this regard, a glitch may induce transitions 222 and 224 on the ‘latch_enable’ and ‘match’ signals, resulting in the ‘match_reg’ signal being set to logic 1 at transition 226. When the glitch subsides, the ‘latch_enable’ and ‘match’ signals return to legitimate values at transitions 223 and 225. However, because ‘latch_enable’ signal has returned to logic 0, the ‘match_reg’ value retains the illegitimate logic 1.

FIG. 2C is a timing diagram illustrating how a glitch attack may bypass security features in a system such as the system 200 of FIG. 1A. Referring to FIG. 2C, the timing diagram illustrates the effect of a glitch attack on the ‘A’, ‘B’, ‘compare_enable’, and ‘match’, signals described in FIG. 2A. In this regard, a glitch may induce transitions 242, 244 and 246 on the ‘A’, ‘B’, and ‘compare_enable’ lines making all bits equal to logic 1 simultaneously. Because ‘compare_enable’ is logic 1, and ‘A’ and ‘B’ are the same, i.e. all 1's, ‘match’ is set to logic 1 at transition 246. When the glitch subsides, ‘A’, ‘B’, and ‘compare_enable’ return to legitimate values at transitions 243, 245, and 247. However, because ‘compare_enable’ has returned to logic 0, ‘match’ retains an illegitimate logic 1. Consequently, if ‘latch_enable’ goes to logic one at some later transition 250, then ‘match_reg’ may be set to an illegitimate logic 1 as shown by transition 252.

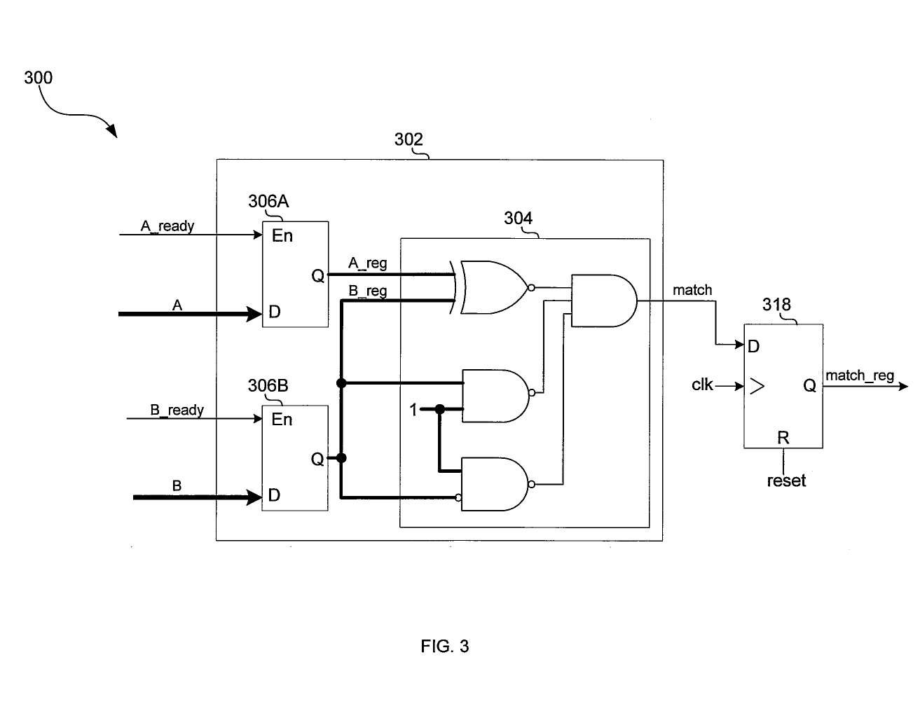

FIG. 3 is a block diagram an exemplary glitch protected system, in accordance with an embodiment of the invention. Referring to FIG. 3 the system may comprise comparison block 302 and a register 318.

The comparison block 302 may comprise registers 306A, 306B and a combinational logic block 304. The registers 306A, 306B, which may be collectively referred to as registers 306, may comprise suitable logic, circuitry, and/or code which may enable storing data. In this regard, each of the registers 306A, 306B may receive data comprising a plurality of bits and may enable storing the data when an enable signal may be logic 1. In this manner, the register 306A may store a value ‘A’ upon receiving a logic 1 on a signal ‘A_ready’, and the register 306B may store a value ‘B’ upon receiving a logic 1 on a signal ‘B_ready’. In this regard, values ‘A’ and ‘B’ may require some processing and/or calculation and thus the registers 306 may enable preventing erroneous values from affecting a ‘match’ signal while ‘A’ and/or ‘B’ may be settling. In various embodiments of the invention, the registers 306 may be any type and/or size of storage element such as level sensitive and/or edge-triggered latches and/or flip-flops.

The combinational logic block 304 may comprise suitable logic, circuitry, and/or code which may enable comparing ‘A’, ‘B’, and at least one of a value comprising all logic 1's and a value comprising all logic 0's. In this regard, the ‘match’ value may go to logic 1 if ‘A’ and ‘B’ are the same value but not if the value comprises all logic 0’s or all logic 1's. An exemplary embodiment of the combinational logic block 304 may comprise 4 logic gates is shown in FIG. 3.

The register 318 may comprise suitable logic, circuitry, and/or code which may enable storage data. In this regard, the register 318 may be permanently enabled such that ‘match_reg’ follows ‘match’. For example, the ‘match’ value may be stored as ‘match_reg’ on every negative transition of a clock. In various embodiments of the invention, the register 318 may be any type and/or size of storage element such as level sensitive and/or edge-triggered latches and/or flip-flops. The register 318 may be utilized, for example, to delay ‘match’ or synchronize it to a clock signal. In various embodiments of the invention, ‘match’ may be utilized directly and the system 300 may not comprise the register 318.

In operation, the system 300 may prevent a glitch attack, such as the one shown in FIG. 2C, from forcing the ‘match_reg’ to an illegitimate logic 1. In this regard, because ‘A’ and ‘B’ may comprise a plurality of bits, the most likely glitch attack on the registers 306 would be to force ‘A_reg’ and ‘B_reg’ to all logic 1's or all logic 0's. In this regard, the system 300 may be designed such that ‘A’ and ‘B’ should never be all 0's or all 1's. Accordingly, if the comparison block determines that ‘A_reg’ and ‘B_reg’ comprise all logic 1's or all logic 0's, the value of ‘match’ may be set to logic 0 even though “A_reg’ is the same as ‘B_reg’.

The system 300 may prevent a glitch attack, such as the one shown in FIG. 2B, from forcing ‘match_reg’ to an illegitimate logic 1. In this regard, because ‘match’ is a combinational output, it will return to a legitimate value when a glitch subsides. Additionally, because the register 318 may be updated regularly, for example on every transition of a clock signal, the legitimate value of ‘match’ may be stored as ‘match_reg’ on the clock transition immediately following a glitch subsiding. In this regard, the register 318 may not comprise an enable input that may prevent the contents of the register from being updated.

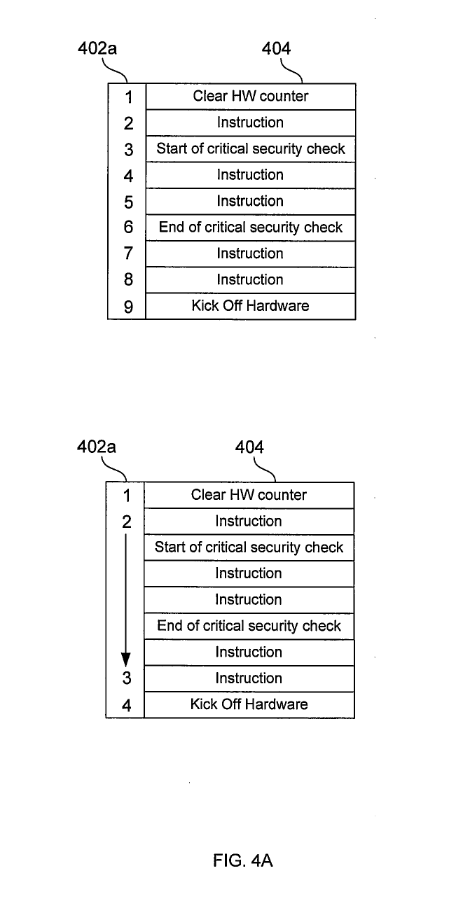

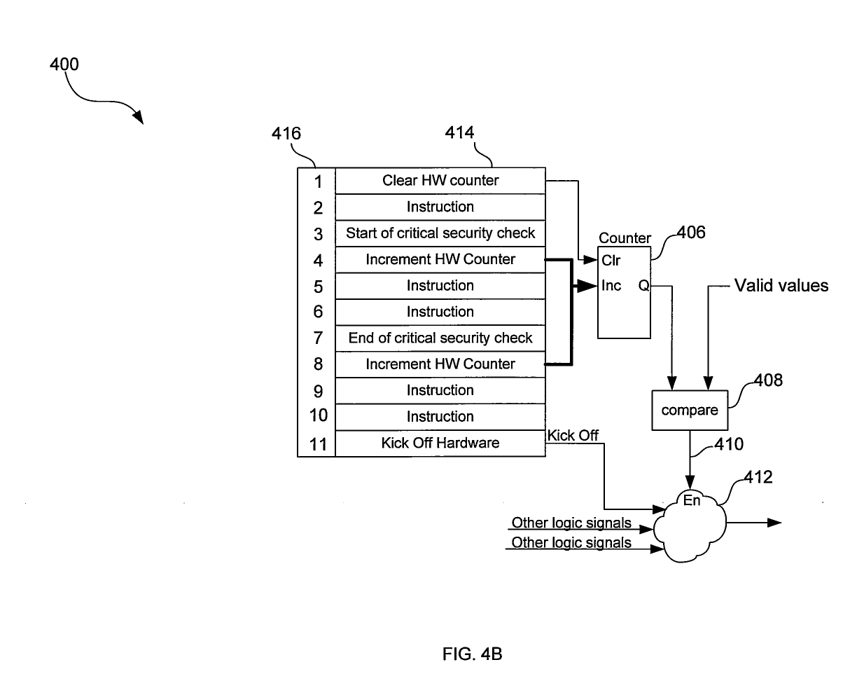

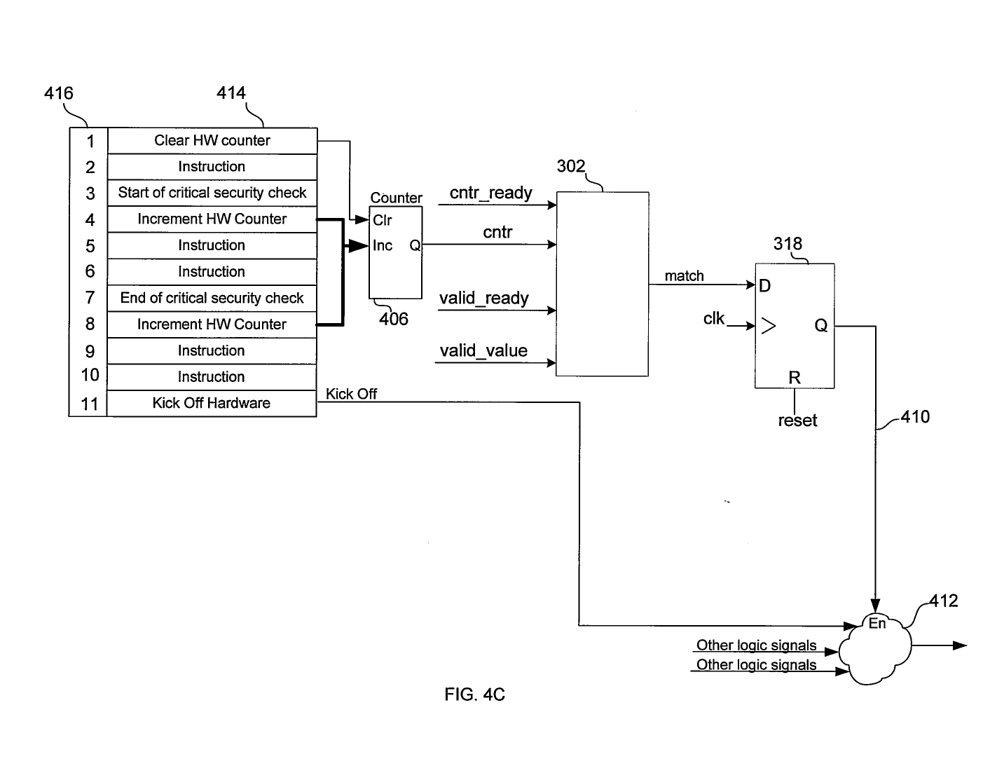

FIG. 4A is a diagram of an exemplary code sequence illustrating the need for glitch protection, in connection with an embodiment of the invention. Referring to FIG. 4A there is shown two instances of an instruction counter 402, and a code sequence 404.

The code sequence 404 may represent an exemplary code sequence which may be executed by a processor such as the processor 106. The code sequence 404 may comprise one or more instructions for performing security checks, and may comprise a ‘kick off hardware” instruction which may enable one or more secure functions in a system such as the system 102. For example, the code sequence 404 may comprise instructions which a processor, such as the processor 106 in FIG. 1, may execute in order to, for example, prevent an unauthorized terminal from executing code from the RAM 110. In this manner, if the security checks fail, the processor 106 may exit the code sequence without executing the ‘kick off hardware’ instruction, thus preventing unauthorized execution of instructions from the RAM 110.

The instruction counter 402 may represent the order in which the instructions comprising the code sequence 404 are executed by the processor 106. In this manner, the ‘1’ through ‘9’ of the instruction counter 402a represents that the 9 instructions comprising the code sequence 404 have been executed in order. In contrast, the ‘1’ through ‘4’ of the instruction counter 402b represents that only 6 of the 9 instructions comprising code sequence 404 have been executed. In this manner, the instruction counter 402b illustrates an instance where a glitch has caused the security instructions to be skipped and hence ‘kick off hardware’ may be executed without performing the security checks. In this regard, ‘kick off hardware’ may comprise performing one or more operations which grant the terminal 116 or the card reader 118 access to the secure functions of the system 102.

FIG. 4B is a diagram of an exemplary glitch protected system, in accordance with an embodiment of the invention. Referring to FIG. 4B is shown a instruction counter 416, a code sequence 414a, a counter 406, a comparison block 408, an enable signal 410, and a subsystem 412.

The instruction counter 416 may represent the order in which the instructions comprising the code sequence 414 are executed by a processor. In this manner, the ‘1’ through ‘11’ of the instruction counter 416 represents that the 11 instructions comprising the code sequence 414 have been executed in order.

The code sequence 414 may comprise an instruction set similar to the code sequence 404a of FIG. 4A. In order to provide glitch protection, however, the code sequence of 414 may comprise additional steps which instruct a processor 106, such as the processor 106, to modify the value of one or more registers. In one embodiment of the invention, the additional instructions may each instruct the processor 106 to increment or decrement a counter, while in other various embodiments of the invention the additional steps may instruct the processor 106 to modify the contents of one or more registers and/or set one or more control/flag bits.

The counter 406 may comprise suitable logic, circuitry, and/or code which may enable determining if one or more instructions comprising the code sequence 414 have been executed. In this regard, the counter 406 may be incremented or decremented when one or more security instructions have been executed. Accordingly, if a glitch attack is utilized to skip over one or more security instructions, the counter 406 may be incremented and/or decremented an invalid number of times. In various embodiments of the invention, the counter may be incremented or decremented when a security instruction is executed or when a branch is reached in the code sequence 404. Additionally, as stated above, various embodiments of the invention may utilize one or more registers in place of the counter 406.

The comparison block 408 may comprise suitable logic, circuitry and/or code which may enable determining if the counter 406 has been incremented or decremented to arrive at a predetermined number and or predetermined range of numbers. In this manner, the code sequence 414 may be arranged such that if all security instructions have been executed, then a value stored in counter 406 may be equal to a predetermined number or range of numbers. If the value stored in the counter 406 is a valid number, then the comparison block 408 may set the enable signal 410 to logic 1. In this regard, the comparison block 408 may be similar or the same as the system 300 in FIG. 3.

The enable signal 410 may enable the subsystem 412 to perform secure operations. For example, in a system such as the system 102 of FIG. 1, the enable signal 410 may enable the processor 106 to execute instructions from the nonvolatile RAM 108.

The subsystem 412 may comprise suitable logic, circuitry, and/or code for implementing/performing one or more secure functions in a secure system such as the system 102, for example. In this regard, the subsystem 412 may represent one or more functions implemented by the processor 106, the nonvolatile RAM 108, and the RAM 110.

FIG. 4C is a diagram illustrating the use of a counter to determine whether code has been executed, in accordance with an embodiment of the invention. Referring to FIG. 4C, there is shown the instruction counter 416, the code sequence 414, the counter 406, the comparison block 302, the register 318, the enable signal 410, and the subsystem 412.

The instruction counter 416, the code sequence 414, the counter 406, the enable signal 410, and the subsystem 412, may be as described with respect to FIG. 4. Similarly, the comparison block 302 and the register 318 may be as described with respect to FIG. 3. In this regard, FIG. 4C illustrates an exemplary manner in which the system 300 may be utilized in combination with the system 400 to provide protection against various types of glitch attacks such as the glitch attacks described above.

Aspects of the invention may be found in a method and system for glitch protection in a secure system. In this regard, the output of an on-chip security operation may be combinatorially compared with an expected output of the security operation. Additionally, the output of the security operation may be compared to a value comprising all logic 0's and/or all logic 1’s, as is shown in the block 304 of FIG. 3. The comparison may be performed by a comparison block the same as or similar to the comparison block 302 of FIG. 3. Based on the results of the comparison, one or more signals which may control access to one or more on-chip secure functions, such as the signals ‘match’ and ‘match_reg’ of FIG. 3 , may be generated on-chip.

The security operation may, for example, comprise generating a message digest utilizing a secure hash algorithm. Also, the security operation may comprise modifying one or more values based on an amount of code being executed, by a processor such as the processor 106. In this regard, the modified value may comprise one or more of a counter, a register value, and a flag. Accordingly, the expected output may be a single value or a range of valid values. Additionally, the amount of code executed may comprise a number of instructions and/or lines of code, such as the code sequence 404 of FIG. 4A, and code sequence 414 of FIGS. 4B, and 4C.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for securing electronic communication and processing of information, the method comprising:
comparing via combinatorial logic integrated within a chip, at least an output of an on-chip security operation with an expected output of said on-chip security operation; and
generating within said chip one or more signals which control access to one or more on-chip secure functions based on said comparison.

2. The method according to claim 1, comprising combinatorially comparing at least a message digest generated by a secure hash algorithm with an expected message digest.

3. The method according to claim 1, wherein said comparison via combinatorial logic integrated within a chip comprises comparing a value comprising all logic 0s with said output of said on-chip security operation and said expected output of said security operation.

4. The method according to claim 1, wherein said comparison via combinatorial logic integrated within a chip comprises comparing a value comprising all logic 1s with said output of said on-chip security operation and said expected output of said on-chip security operation.

5. The method according to claim 1, wherein said expected output comprises a single counter value or a range of valid counter values.

6. The method according to claim 1, comprising modifying one or more values based on an amount of code that is executed for said on-chip security function.

7. The method according to claim 6, wherein said one or more modified values comprise one or more of: a counter value, a register value, and a flag.

8. The method according to claim 6, wherein said amount of code that is executed comprises a number of instructions that are executed and/or a number of lines of code that are executed.

9. The method according to claim 6, comprising combinatorially comparing said one or more modified values to a corresponding determined expected value.

10. The method according to claim 9, comprising controlling access to said one or more on-chip secure functions based on said comparison.

11. The method according to claim 1, comprising storing said one or more signals which control access to one or more on-chip secure functions utilizing registers and the contents of said registers are periodically updated.

12. The method according to claim 11, wherein said periodic updating prevents said one or more signals that control access to one or more on-chip secure functions from being latched to illegitimate values for a period of time sufficient to compromise one or more of said secure functions.

13. A system for securing electronic communication and processing of information, the system comprising:
one or more circuits within a chip comprising combinatorial logic, which compares at least an output of an on-chip security operation with an expected output of said on-chip security operation; and
said one or more circuits generate within said chip one or more signals which control access to one or more on-chip secure functions based on said comparison.

14. The system according to claim 13, wherein said one or more circuits combinatorially compares at least a message digest generated by a secure hash algorithm WITH an expected message digest.

15. The system according to claim 13, wherein said one or more circuits combinatorially compares a value comprising all logic 0s with said output of said on-chip security operation and said expected output of said security operation.

16. The system according to claim 13, wherein said one or more circuits combinatorially compares a value comprising all logic 0s with said output of said on-chip security operation and said expected output of said security operation.

17. The system according to claim 13, wherein said expected output comprises a single counter value or a range of valid counter values.

18. The system according to claim 13, wherein said one or more circuits modifies one or more values based on an amount of code that is executed for said on-chip security function.

19. The system according to claim 18, wherein said one or more modified values comprise one or more of: a counter value, a register value, and a flag.

20. The system according to claim 18, wherein said amount of code that is executed comprises a number of instructions that are executed and/or a number of lines of code that are executed.

21. The system according to claim 18, wherein said one or more circuits combinatorially compares said one or more modified values to a corresponding determined expected value.

22. The system according to claim 21, wherein said one or more circuits controls access to said one or more on-chip secure functions based on said comparison.

23. The system according to claim 13, wherein said one or more circuits enable storing said or more signals which control access to one or more on-chip secure functions utilizing registers and the contents of said registers are periodically updated.

24. The method according to claim 23, wherein said periodic updating prevents said one or more signals that control access to one or more on-chip secure functions from being latched to illegitimate values for a period of time sufficient to compromise one or more of said secure functions.
